(19) United States
(12) Patent Application Publication
(10) Pub. No.: US 2007/0108495 A1
(43) Pub. Date: May 17, 2007

(54) MNOS memory devices and methods for operating an MNOS memory devices

(75) Inventor: Chao-I Wu, Hsinchu (TW)

Correspondence Address: BAKER & MCKENZIE LLP;PATENT DEPARTMENT, 2001 ROSS AVENUE, SUITE 2300, DALLAS, TX, 75201, US

(73) Assignee: Macronix International Co., Ltd.

(21) Appl. No.: 11/281,028

(22) Filed: Nov. 17, 2005

(51) Int. Cl. H01L 29/76

(52) U.S. Cl. 257/314

(57) ABSTRACT

A split-gate MNOS memory device comprises a thin dielectric layer between the memory gate and the silicon nitride trapping layer. The thin dielectric layer can block charge loss at low electric field and can allow hole injection at high electric fields. P-type polysilicon gates can be used to increase hole injection efficiency.

### BACKGROUND

1. Field of the Invention

The invention relates generally to non-volatile memory structures, and more particularly to a split-gate metal-nitride-oxide-silicon structures.

2. Background of the Invention

Metal-Nitride-Oxide-Silicon (MNOS) memory devices are charge trapping devices where charge, or data is stored in discrete nitride traps within a trapping layer. The charge can also be retained when power is removed. Thus, MNOS memory devices can be used for non-volatile memory applications.

Split-gate MNOS memory devices were developed in order to improve on the performance of conventional MNOS memory devices. FIG. 1 is a diagram illustrating a conventional split-gate MNOS memory device 100. As can be seen, MNOS memory structure 100 comprises a substrate 101. In this case, substrate 101 is a P-type substrate. N⁺ Source and drain regions, 102 and 104 respectively, have been implanted in substrate 101. An oxide layer 106 is then grown on substrate 101 between source and drain regions 102 and 104. A silicon nitride layer 108 is then grown on top of oxide layer 106. Silicon nitride layer 108 provides the nitride traps for charge trapping in device 100.

MNOS memory device 100 comprises two gate structures, a control gate 112 and a memory gate 110. Control gate 112 is separated from control gate 110 by an oxide layer 114. The dual gate structure 100 is referred to as a split-gate MNOS memory device. Device 100 can be programmed, i.e., charge can be stored in silicon nitride layer 108 via a process known as source side hot electron injection. During this process, programming voltages are applied to device 100 that will cause electrons to migrate from source 102 into silicon nitride layer 108. The charge migrates from source 102 to silicon nitride layer 108 by tunneling through oxide layer 106.

The process of source side hot electron injection is illustrated in FIG. 2. As illustrated in FIG. 2, programming voltages can be applied to control gate 112, memory gate 110, source 103, drain 104, and substrate 101. In this particular example, a programming voltage of 1.5V is applied to control gate 112, while a programming voltage of 10V is applied to memory gate 110, and a programming voltage of 5V is applied to drain 104. Both source 102 and substrate 101 can be tied to 0V. These programming voltages will cause electrons 202 to begin to migrate into a channel region between source 102 and drain 104. A certain number of the electrons will have enough charge to tunnel through oxide layer 106 into region 204 of silicon nitride layer 108. The electrons accumulated in region 204 will change the threshold voltage (V_{T}) of device 100 from a low, erase level to a high, program level.

FIG. 3 is a diagram illustrating how device 100 can be erased once it is programmed using the process illustrated in FIG. 2. In FIG. 3, various erased voltages are applied to device 100 in order to cause holes to migrate from memory gate 110 into silicon nitride region layer 108 in order to compensate for holes 202 trapped in region 204. In the example of FIG. 3, a 1.5V erased voltage is applied to control gate 112 and a 15V erased voltage is applied to memory gate 110. Source 102, drain 104, and substrate 101 are all tied to 0V. The large electrical field created between substrate 101 and memory gate 110 by the programming voltages will cause holes in memory gate 110 to tunnel through the barrier between memory gate 110 and silicon nitride layer 108.

While the structure of device 100 illustrated in FIGS. 1-3 can improve the performance of conventional MNOS memory devices in certain respects, device 100 can still suffer from certain disadvantages such as charge loss from silicon nitride layer 108 to control gate 110 when there is a low electrical field between gate 110 and substrate 101. Further, the hole injection efficiency for device 100 can be improved upon.

### SUMMARY

A split-gate MNOS memory device comprises a thin oxide layer between the memory gate and the silicon nitride trapping layer. The thin oxide layer can block charge loss at low electric field and can allow hole injection at high electric fields.

In one aspect, P-type polysilicon gates can be used to increase hole injection efficiency.

These and other features, aspects, and embodiments of the invention are described below in the section entitled “Detailed Description.”

### BRIEF DESCRIPTION OF THE DRAWINGS

Features, aspects, and embodiments of the inventions are described in conjunction with the attached drawings, in which:

FIG. 1 is a diagram illustrating an exemplary split-gate MNOS memory device;

FIG. 2 is a diagram illustrating a programming operation for the device of FIG. 1;

FIG. 3 is a diagram illustrating an erase operation for the device of FIG. 1;

FIG. 4 is a diagram illustrating a split-gate MNOS memory device configured in accordance with one embodiment;

FIG. 5 is a diagram illustrating a programming operation for the device of FIG. 4;

FIG. 6 is a diagram illustrating an erase operation for the device of FIG. 4;

FIG. 7 is a diagram illustrating an example of split-gate MNOS memory device configured in accordance with another embodiment;

FIG. 8 is a diagram illustrating an example split-gate MNOS memory device configured in accordance with still another embodiment;

FIG. 9 is a diagram illustrating an example split-gate MNOS memory device configured in accordance with still another embodiment;

FIG. 10 is a diagram illustrating an example split-gate MNOS memory device configured in accordance with still another embodiment;

FIG. 11 is a diagram illustrating an example split-gate MNOS memory device configured in accordance with still another embodiment;

FIG. 12 is a diagram illustrating an example split-gate MNOS memory device configured in accordance with still another embodiment;

FIG. 13 is a diagram illustrating an example split-gate MNOS memory device configured in accordance with still another embodiment;

FIG. 14 is a diagram illustrating an example split-gate MNOS memory device configured in accordance with still another embodiment;

FIG. 15 is a diagram illustrating an example split-gate MNOS memory device configured in accordance with still another embodiment;

FIG. 16 is a diagram illustrating an example split-gate MNOS memory device configured in accordance with still another embodiment;

FIG. 17 is a diagram illustrating an example split-gate MNOS memory device configured in accordance with still another embodiment;

FIG. 18 is a diagram illustrating an example split-gate MNOS memory device configured in accordance with still another embodiment;

FIG. 19 is a diagram illustrating an example split-gate MNOS memory device configured in accordance with still another embodiment;

FIG. 20 is a diagram illustrating an example split-gate MNOS memory device configured in accordance with still another embodiment;

FIG. 21 is a band diagram for a split-gate MNOS memory device under a high electric field; and

FIG. 22 is a band diagram for a split-gate MNOS memory device under a low electric field.

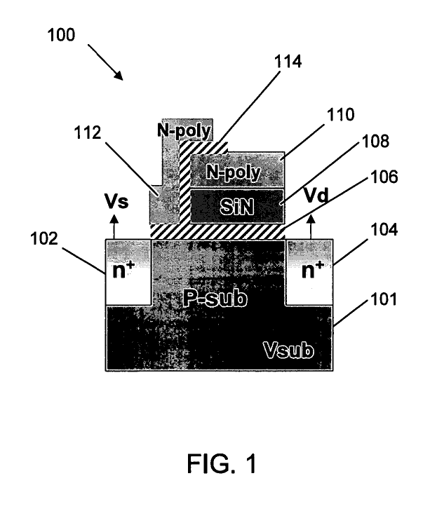

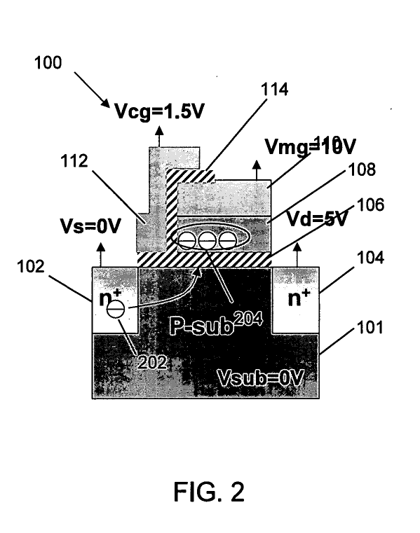

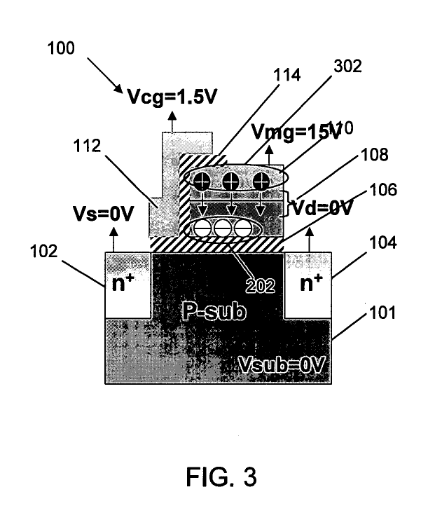

### DETAILED DESCRIPTION OF THE PREFERRED EMBODIMENTS

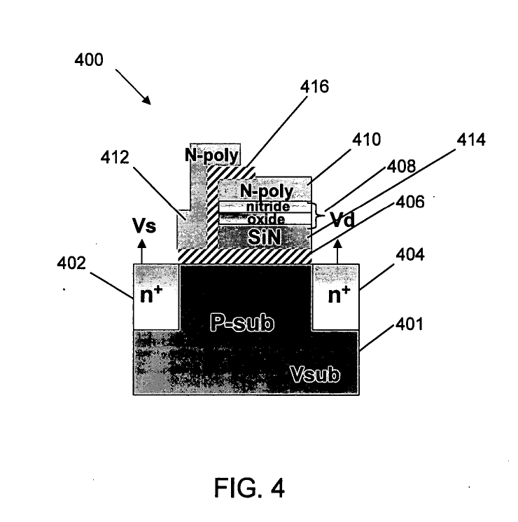

FIG. 4 is a diagram illustrating an example of split-gate MNOS memory device configured in accordance with one embodiment described herein. MNOS memory device 400 comprises a P-type substrate 401 with N-type source and drain regions, 402 and 404 respectively, implanted therein. A dielectric layer, such as an oxide layer, 406 is then grown on substrate 401 between source and drain regions 402 and 404. A silicon nitride trapping layer 414 is then grown on top of dielectric layer 406. Device 400 also comprises a control gate 412 and memory gate 410. In this case, control gate 412 and memory gate 410 are both N-type poly-silicon structures. Control 412 is separated from memory gate 410 by a dielectric layer, such as layer 408.

Unlike conventional split-gates MNOS memory devices, however, device 400 comprises a thin dielectric layer 408 between memory gate 410 and silicon nitride trapping layer 414. In the example of FIG. 4, thin dielectric layer 408 actually comprises a thin nitride layer above a thin dielectric layer. As will be explained below, in other embodiments, thin dielectric layer 408 can comprise a single oxide layer, an oxide layer and a nitride layer as in the example of FIG. 4, or a nitride layer sandwiched between two oxide layers. As will also be explained below, control gate 412 and memory gate 410 can comprise N-type poly-silicon structures as in the example of FIG. 4, P-type poly-silicon structures, or some combination thereof.

Thin dielectric layer 408 can allow hole injection at high electrical fields, but can also block charge loss at low electrical fields.

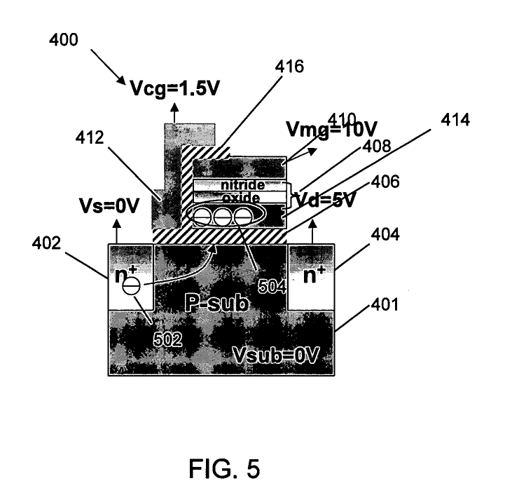

FIG. 5 is a diagram illustrating a programming operation for device 400. As with conventional devices, source side hot electron injection can be used in order to trap charge in silicon nitride trapping layer 414. Thus, when the appropriate programming voltages are applied, electrons 502 can begin to migrate between source 402 and drain 404 and tunnel through dielectric layer 406 into region 504 of silicon nitride layer 414.

In the example of FIG. 5, a voltage between about 1-3V, e.g., a 1.5V programming voltage, is applied to control gate 412, a voltage between about 8˜12V, e.g., a 10V programming voltage, is applied to memory gate 410, and a voltage between about 4˜6V, e.g., 5V programming voltage, is applied to drain 404. It will be clear, however, that other programming voltages can be used and that the programming voltages illustrated in FIG. 5 are by way of example only. Source 402 and substrate 401 can be tied to 0V during the programming operation.

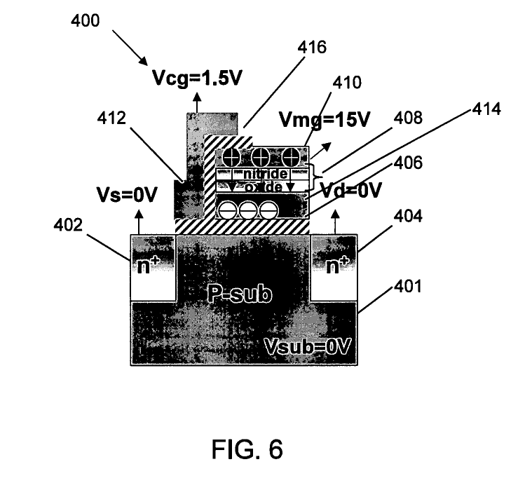

FIG. 6 is a diagram illustrating an erase operation for device 400. As can be seen, holes 610 can tunnel through thin dielectric layer 408 and compensate for electrons 502 stored in region 504 of silicon nitride layer 414. A high electric field is created between memory gate 410 and substrate 401 in order to cause holes 602 to tunnel through thin oxide layer 408 and into silicon nitride layer 414. In the example of FIG. 6, an erase voltage between approximately 1˜3V, e.g., 1.5V, is applied to control gate 412, while an erase voltage between approximately 12˜16V, e.g., 15V, is applied to memory gate 410. Source 402, drain 404, and substrate 401 can all be tied to 0V. It will be clear, however, that the voltages illustrated in FIG. 6 are by way of example only and that other voltages can be used depending on the embodiment.

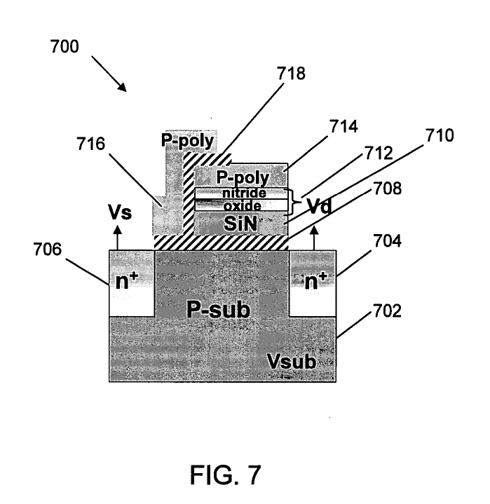

Because thin dielectric layer 408 can block charge loss at low electric field, device 400 can provide better data retention as compared to conventional split-gate MNOS memory devices. Further, increased hole injection efficiency during the erase operation of FIG. 6 can be achieved by using P-type poly-silicon gate structures for the control gate and/or the memory gate. FIG. 7 is a diagram illustrating an example split-gate MNOS memory structure 700 comprising a P-type poly-silicon control gate 716 and a P-type poly-silicon memory gate 714 in accordance with one of the embodiments described herein. Thus, device 700 comprises a P-type substrate 702 with N-type source and drain regions, 706 and 704 respectively, implanted therein. A dielectric layer, e.g., oxide layer 708, is then grown on substrate 702. A silicon nitride trapping layer 710 can then be grown on oxide layer 708.

In the example of FIG. 7, a thin dielectric layer 712 comprises a thin nitride layer and a thin oxide layer as in the example of FIG. 4. Further, P-type poly-silicon gate structures 716 and 714 are separated by a dielectric layer, e.g., oxide layer 718.

Device 700 can be programmed and erased in much the same way as described above in relation to device 400; however, due to the use of P-type poly-silicon memory gate structure 714, the efficiency of hole injection from memory gate 714 through thin dielectric layer 712 into silicon nitride layer 710 during the erase operation is improved. This increased efficiency can reduce erase times and increase the read window.

FIG. 8 is a diagram illustrating an example split-gate MNOS structure 800 comprising an N-type poly-silicon control gate 816 and a P-type poly-silicon memory gate 814 in accordance with another embodiment described herein. Thus, device 800 can provide the increased data retention due to thin oxide layer 812 as well as increased hole injection efficiency due to the P-type poly-silicon memory gate structure 814.

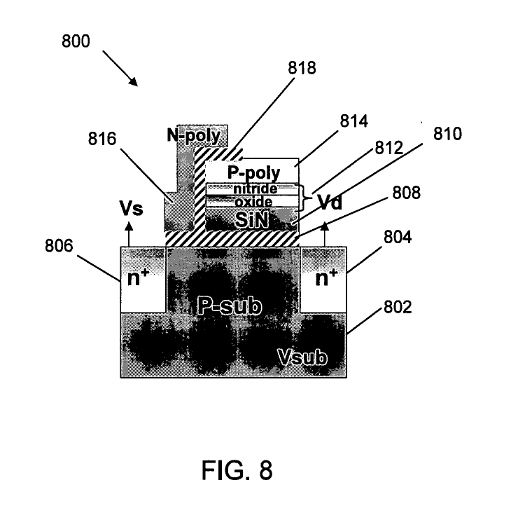

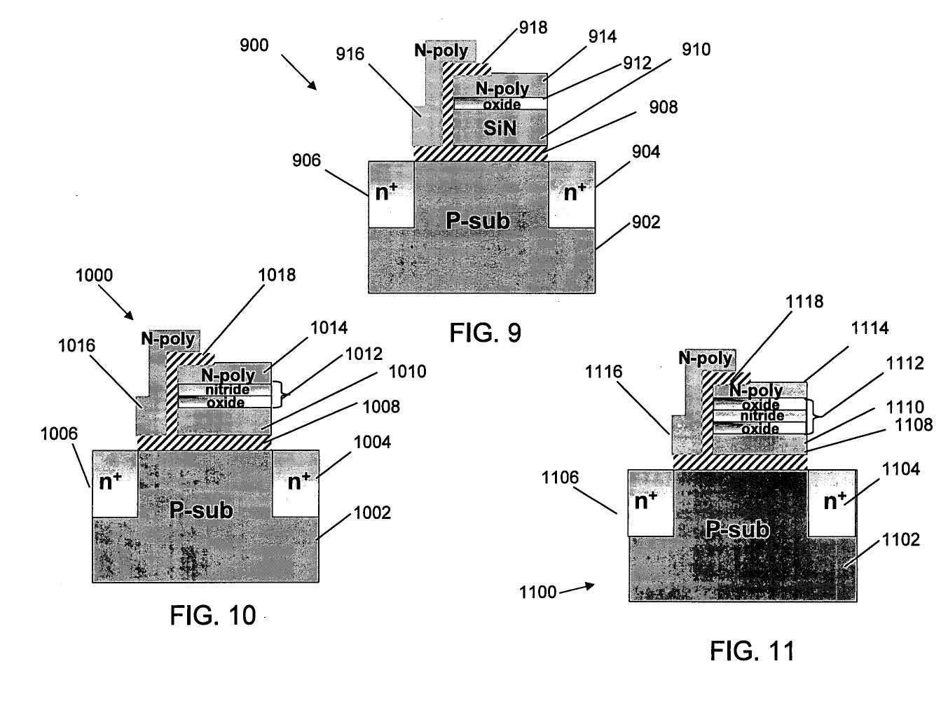

As mentioned above, split-gate MNOS memory devices configured in accordance with the embodiments described herein can comprise various thin dielectric layer structures and combinations of gate structures. Various different embodiments of split-gate MNOS memory structures are described in relation to FIGS. 9-20.

In FIGS. 9-11, embodiments of split-gate MNOS memory structures are illustrated that comprise N-type poly-silicon control gate and memory gate structures. In FIG. 9, a split-gate MNOS memory device 900 is illustrated that comprises N-type poly-silicon control gate 916 and N-type poly-silicon memory gate 914 separated by oxide layer 918. Device 900 comprises a thin dielectric layer 912 that comprises a single thin oxide layer.

FIG. 10 is a diagram illustrating a split-gate MNOS memory device structure 1000 that also comprises an N-type poly-silicon control gate 1016 separated from an N-type poly-silicon memory gate 1014 by oxide layer 1018. In the example of FIG. 10, as in the example of FIG. 4, thin dielectric layer 1012 comprises a thin nitride layer and a thin oxide layer.

FIG. 11 is a diagram illustrating an example of split-gate MNOS memory device 1100 that comprises N-type poly-silicon gate 1116 separated from N-type poly-silicon memory gate 1114 by oxide layer 1118. Device 1100 comprises a thin dielectric layer 1112 that comprises a thin nitride layer sandwiched between upper and lower thin oxide layer.

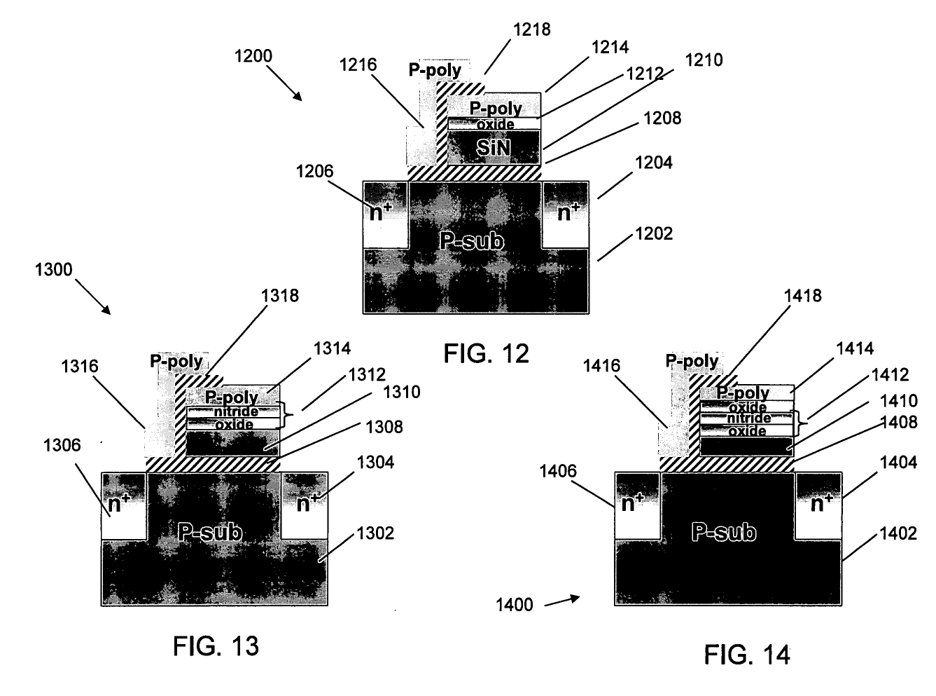

Each of devices 900, 1000, and 1100 can provide higher data retention as compared to conventional split-gate MNOS memory devices due to thin dielectric layers 912, 1012, and 1112. FIGS. 12-14 illustrate example split-gate MNOS memory structures that use P-type poly-silicon control gates and memory gates in order to provide increased hole injection efficiency. Thus, FIG. 12 is a diagram illustrating an example of split-gate MNOS memory device 1200 comprising P-type poly-silicon control gate 1216 separated from P-type poly-silicon memory gate 1214 by oxide layer 1218. Device 1200 comprises a thin dielectric layer 1212 that includes a single thin oxide layer.

Device 1300 of FIG. 13 also comprises a P-type poly-silicon control gate 1316 separated from a P-type poly-silicon memory gate 1314 by an oxide layer 1318; however, device 1300 comprises a thin dielectric layer 1312 that includes a thin nitride layer and a thin oxide layer similar to device of FIG. 7.

FIG. 14 is a diagram illustrating an example split-gate MNOS memory device 1400 that comprises a thin dielectric layer 1412 that includes a thin nitride layer sandwiched between upper and lower oxide layers.

Again, devices 1200, 1300, and 1400 provide better data retention as compared to conventional split-gate MNOS memory devices due to the inclusion of thin dielectric layers 1212, 1312, and 1412. In addition, devices 1200, 1300, and 1400 can provide increased hole injection efficiency due to the use of P-type poly-silicon gate structures.

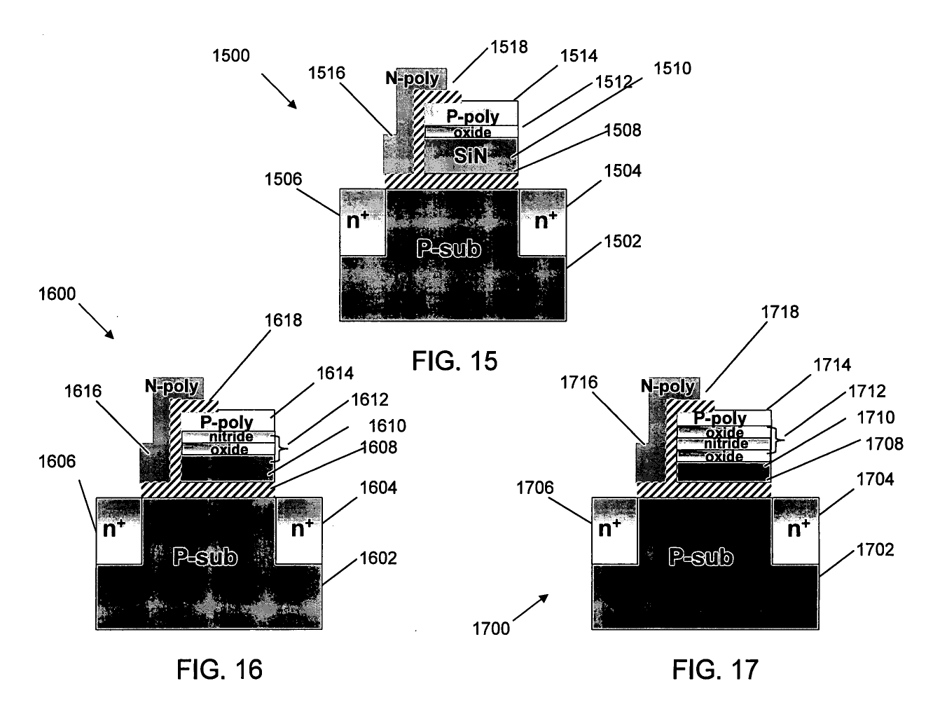

FIGS. 15-17 illustrate example split-gate MNOS memory devices 1500, 1600, and 1700 respectively, that include N-type poly-silicon control gates 1516, 1616, and 1716, but use P-type poly-silicon memory gates 1514, 1614, and 1714 respectively. Thus, devices 1500, 1600, and 1700 provide increased data retention as well as increased hole injection efficiency.

As can be seen, device 1500 includes a thin dielectric layer 1512 comprising a single thin oxide layer, while device 1600 includes a thin dielectric layer 1612 that comprises a thin nitride layer and a thin oxide layer as with the example of FIG. 8. Device 1700 comprises a thin dielectric layer 1712 that comprises a thin nitride layer sandwiched between upper and lower oxide layers.

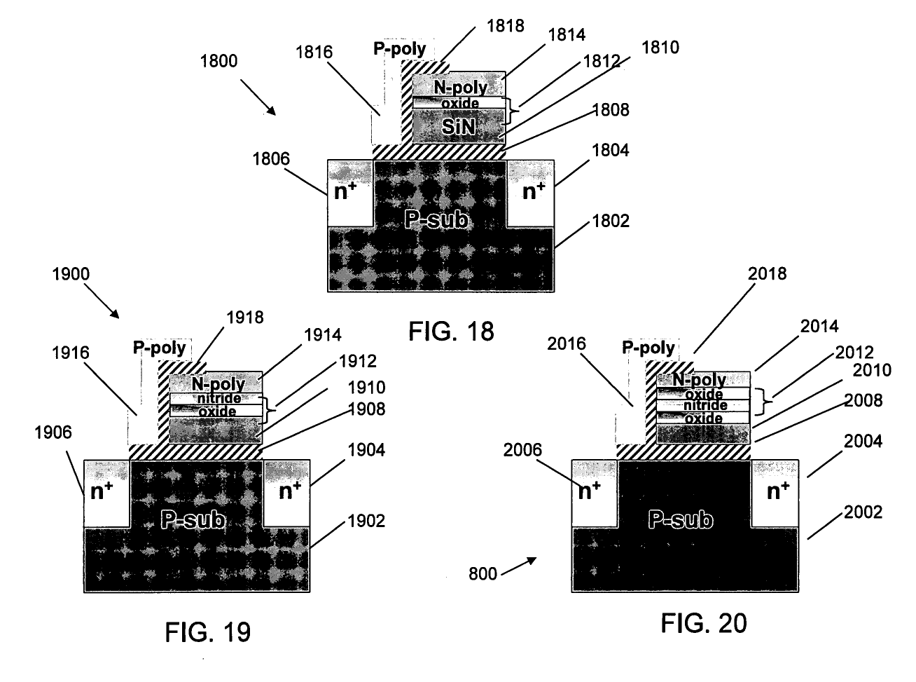

FIGS. 18-20 illustrate example split-gate MNOS memory devices 1800, 1900, and 2000 that include P-type poly-silicon control gates 816, 916, 2016, and N-type poly-silicon memory gates 1814, 1914, and 2014, respectively. Device 1800 includes a thin dielectric layer 1812 that includes a single thin oxide layer, while device 1900 comprises a thin dielectric layer 1912 comprising a thin nitride layer and a thin oxide layer. Device 2000 comprises a thin dielectric layer 2012 comprising a thin nitride layer sandwiched between upper and lower oxide layers.

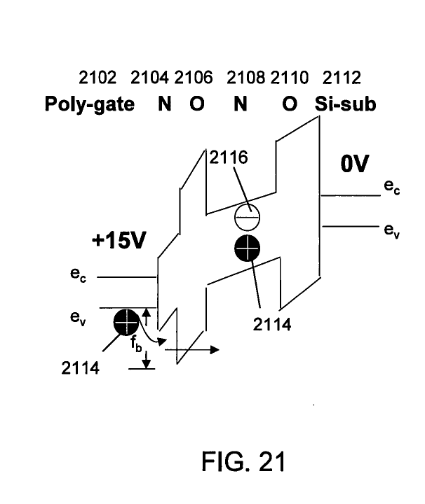

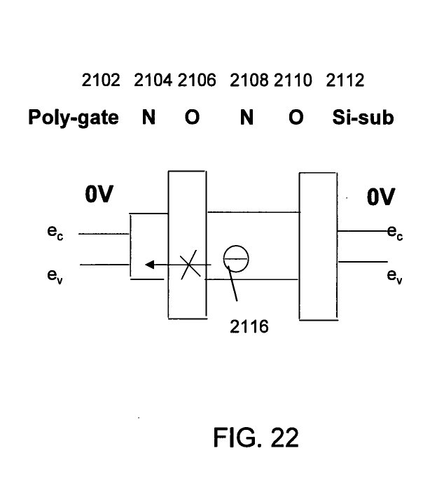

As noted above, the use of a thin dielectric layer between the memory gate and the silicon nitride trapping layer can improve data retention by allowing holes to tunnel across the thin oxide layer under a high electric field while preventing charge loss during low electric field conditions. This can be illustrated with the band diagrams of FIGS. 21 and 22. FIG. 21 illustrates the band diagram for a split-gate MNOS memory device comprising a poly-silicon gate 2102 separated from a nitride trapping layer 2108 by a thin dielectric layer. In this case, the thin dielectric layer comprises a nitride layer 2104 and an oxide layer 2106. Nitride trapping layer 2108 is separated from a silicon substrate 2112 by an oxide layer 2110.

In FIG. 21, e_{c} and eᵥ are the conduction and valence bands respectively, fb is the energy barrier between poly-silicon gate 2102 and the thin oxide layer. The approximately 15V erase voltage applied to poly-silicon gate 2102 creates an electric field resulting in a potential barrier. This barrier provides a path for holes 2114 in memory gate 2102 to tunnel through the thin dielectric layer and eventually be collected in nitride trapping layer 2108. Holes 2114 in trapping layer 2108 can compensate for electrons 2116 trapped in trapping layer 2108. The bending of the energy bands for the various layers are different due to the thickness differences between the layers. This is why a thin dielectric layer is used between memory gate 2102 and nitride trapping layer 2108.

FIG. 22 illustrates a band diagram under a no bias condition. In other words, both silicon substrate 2112 and memory gate 2102 are at approximately 0V. Under the conditions of FIG. 22, electrons 2116 in silicon nitride trapping layer 2108 are trapped in layer 2108 by the thin dielectric layer, in this case comprising a thin nitride layer 2104 and thin oxide layer 2106. Thus, the band diagram of FIG. 22 illustrates that a split-gate MNOS memory device configured in accordance with the embodiments described herein can provide greater data retention by trapping electrons 2116 in nitride trapping layer 2108.

In certain other embodiments, a split-gate MNOS memory device configured in accordance with the embodiments described herein can be configured for multi-layer charge (MLC) operation. The ability to prevent charge loss provided by split-gate MNOS memory devices configured in accordance with the embodiments described herein can aid in MLC operation by preventing charge loss and helping to maintain the charge of the various levels needed for MLC operation.

In other embodiments, the control gate of a split-gate MNOS memory device configured in accordance with the embodiments described herein can be constructed from metal layers in addition to the N-type poly-silicon and P-type poly-silicon structures described herein. Further, the silicon nitride trapping layers can be replaced by other trapping material depending on the embodiment.

While certain embodiments of the inventions have been described above, it will be understood that the embodiments described are by way of example only. Accordingly, the inventions should not be limited based on the described embodiments. Rather, the scope of the inventions described herein should only be limited in light of the claims that follow when taken in conjunction with the above description and accompanying drawings.

What is claimed:

1. A non-volatile memory device, comprising:
a trapping layer;
a control gate;
a memory gate separated from the control gate by a dielectric layer; and
a thin dielectric layer sandwiched between the memory gate and the trapping layer.

2. The non-volatile memory device of claim 1, further comprising a source and drain region under the trapping layer.

3. The non-volatile memory device of claim 2, further comprising a oxide layer between the trapping layer and the source and drain regions.

4. The non-volatile memory device of claim 1, wherein the trapping layer comprises a nitride trapping layer.

5. The non-volatile memory device of claim 4, wherein the nitride trapping layer is a silicon nitride trapping layer.

6. The non-volatile memory device of claim 1, wherein the control gate comprises a metal control gate structure.

7. The non-volatile memory device of claim 1, wherein the control gate comprises a N-type polysilicon control gate structure.

8. The non-volatile memory device of claim 1, wherein the control gate comprises a P-type polysilicon control gate structure.

9. The non-volatile memory device of claim 1, wherein the memory gate comprises a metal control gate structure.

10. The non-volatile memory device of claim 1, wherein the memory gate comprises a N-type polysilicon control gate structure.

11. The non-volatile memory device of claim 1, wherein the memory gate comprises a P-type polysilicon control gate structure.

12. The non-volatile memory device of claim 1, wherein the thin dielectric layer comprises a single thin oxide layer.

13. The non-volatile memory device of claim 1, wherein the thin dielectric layer comprises a thin nitride layer and a thin oxide layer.

14. The non-volatile memory device of claim 1, wherein the thin dielectric layer comprises a thin nitride alyer sandwiched between upper and lower thin oxide layers.

15. The non-volatile memory device of claim 1, wherein the trapping layer is configured to trap multiple charge levels.

16. A method for programming a non-volatile memory device comprising a trapping layer, a control gate, a memory gate separated from the control gate by a dielectric layer, and a thin dielectric layer sandwiched between the memory gate and the trapping layer, and a drain and source region, the method comprising:
applying a control gate programming voltage to the control gate;
applying a memory gate programming voltage to the memory gate;
applying a drain programming voltage to the drain region; and
applying 0V to the source.

17. The method of claim 16, wherein the control gate programming voltage is about 1˜3V.

18. The method of claim 16, wherein the memory gate programming voltage is about 8˜12V.

19. The method of claim 16, wherein the drain programming voltage is about 4˜6V.

20. A method for erasing a non-volatile memory device comprising a trapping layer, a control gate, a memory gate separated from the control gate by an dielectric layer, and a thin dielectric layer sandwiched between the memory gate and the trapping layer, and a drain and source region, the method comprising:
applying a control gate erase voltage to the control gate;
applying a memory gate erase voltage to the memory gate; and
applying 0V to the source and drain.

21. The method of claim 20, wherein the control gate erase voltage is about 1˜3V.

22. The method of claim 20, wherein the memory gate erase voltage is about 12˜16V.
